(19) United States
(12) Patent Application Publication
(10) Pub. No.: US 2014/0061759 A1
(43) Pub. Date: Mar. 6, 2014

(54) NONVOLATILE MEMORY DEVICE AND METHOD FOR FABRICATING THE SAME

(71) Applicant: SK HYNIX INC., Gyeonggi-do (KR)

(72) Inventors: Byung-In LEE, Gyeonggi-do (KR); Tae-Gyun KIM, Gyeonggi-do (KR)

(73) Assignee: SK HYNIX INC., Gyeonggi-do (KR)

(21) Appl. No.: 13/716,346

(22) Filed: Dec. 17, 2012

(30) Foreign Application Priority Data
Aug. 30, 2012 (KR) 10-2012-0095700

(51) Int. Cl. H01L 29/788; H01L 29/49

(52) U.S. Cl. CPC H01L 29/788; H01L 29/49
USPC 257/321; 438/594

(57) ABSTRACT

A nonvolatile memory device includes a plurality of gate structures, each gate structure formed over a substrate and including a tunnel insulating layer, a floating gate, an inter-gate dielectric layer, and a control gate, which are sequentially stacked, and an interlayer dielectric layer covering the plurality of gate structures and having an air gap formed between adjacent gate structures, wherein the bottom surface of the air gap is positioned at a lower level than the surface of the tunnel insulating layer.

### CROSS-REFERENCE TO RELATED APPLICATIONS

The present application claims priority of Korean Patent Application No. 10-2012-0095700, filed on Aug. 30, 2012, which is incorporated herein by reference in its entirety.

### BACKGROUND

1. Field

Exemplary embodiments of the present invention relate to a nonvolatile memory device and a method for fabricating the same, and more particularly, to a nonvolatile memory device including an air gap formed between gate structures and a method for fabricating the same.

2. Description of the Related Art

A nonvolatile memory device maintains data stored therein even though power supply is cut off. For example, a NAND-type flash memory device and the like are widely used.

The nonvolatile memory device includes a plurality of gate structures each including a tunnel insulating layer, a floating gate, an interlayer dielectric layer, and a control gate, which are sequentially stacked. Here, each of the floating gates forms a unit memory cell as a charge storage element.

Recently, however, with the increase in integration of semiconductor devices, the design rule has shrunk. Accordingly a gap between gate structures has decreased to increase inter-cell interference, thereby causing various problems. When the inter-cell interference increases, it is impossible to acquire a desired cell distribution. In order to solve such a problem, a technology for forming an air gap between gate structures instead of an insulating material has been developed. When the air gap formation technology is used, it is possible to prevent the inter-cell interference up to a predetermined level of design rule.

However, when the design rule of a nonvolatile memory device shrinks to the predetermined level, inter-cell interference may not be prevented even though the air gap formation technology is used, and a desired cell distribution may not be acquired. Therefore, there is a demand for the development of technology that may overcome such a limit.

### SUMMARY

Exemplary embodiments of the present invention are directed to a nonvolatile memory device and a method for fabricating the same, which may prevent inter-cell interference despite the reduction in design rule, thereby acquiring a desired cell distribution.

In accordance with an exemplary embodiment of the present invention, a nonvolatile memory device includes a plurality of gate structures formed over a substrate, wherein each gate structure includes a tunnel insulating layer, a floating gate, an inter-gate dielectric layer, and a control gate, which are sequentially stacked over the substrate; and an interlayer dielectric layer covering the plurality of gate structures and having an air gap formed between a gate structure and another gate structure adjacent thereto, wherein the bottom surface of the air gap is positioned at a lower level than the surface of the tunnel insulating layer.

In accordance with another exemplary embodiment of the present invention, a method for fabricating a nonvolatile memory device includes forming a first insulating layer for a tunnel insulating layer, a material layer for a floating gate, a second insulating layer for an inter-gate insulating layer, and a conductive layer for a control gate, over a substrate; selectively etching the conductive layer and the second insulating layer; etching the material layer exposed by the etching of the conductive layer and the second insulating layer; forming a plurality of gate structures, wherein each gate structure is formed by etching at least a part of the first insulating layer exposed by the etching of the material layer, and each gate structure includes a tunnel insulating layer, a floating gate, an inter-gate dielectric layer, and a control gate, which are stacked therein; and forming an interlayer dielectric layer covering the plurality of gate structures and having an air gap formed between a gate structure and another gate structure adjacent thereto, wherein the bottom surface of the air gap is positioned at a lower level than the surface of the tunnel insulating layer.

In accordance with further another exemplary embodiment of the present invention, a method for fabricating a nonvolatile memory device includes forming a plurality of gate structures over a substrate, wherein each gate structure includes a tunnel insulating layer; and forming an interlayer dielectric layer covering the plurality of gate structures and having an air gap formed between a gate structure and another gate structure adjacent thereto, wherein the bottom surface of the air gap is positioned at a lower level than the surface of the tunnel insulating layer.

### BRIEF DESCRIPTION OF THE DRAWINGS

FIG. 1 is a plan view of a nonvolatile memory device in accordance with an exemplary embodiment of the present invention.

FIGS. 2A to 4B are cross-sectional views of nonvolatile memory devices in accordance with various exemplary embodiments of the present invention.

FIGS. 5A to 5C are cross-sectional views illustrating a method for fabricating the nonvolatile memory device in accordance with the exemplary embodiment of the present invention.

FIG. 6 is a graph showing an effect of the present invention.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

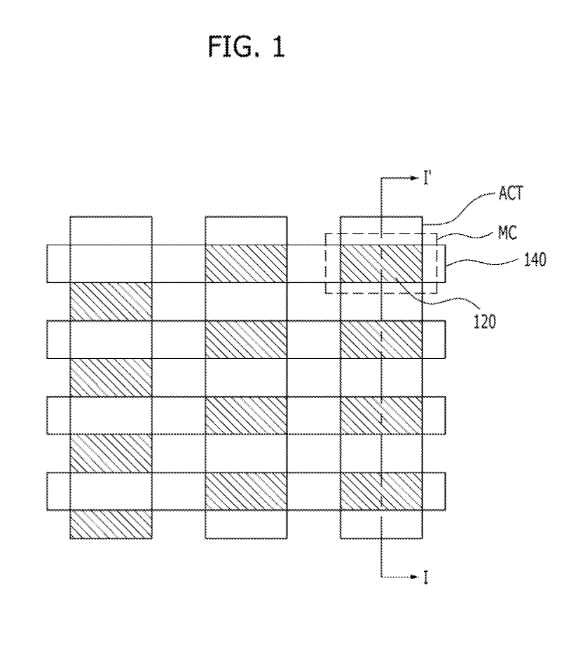

FIG. 1 is a plan view of a nonvolatile memory device in accordance with an exemplary embodiment of the present invention.

Referring to FIG. 1, a plurality of active areas ACT is defined in a substrate. The plurality of active areas ACT is extended in a first direction (I-I′ direction) and arranged in parallel to each other. Over the substrate, a plurality of control gates 140 is formed. The plurality of control gates 140 is extended in a second direction crossing the plurality of active areas ACT and arranged in parallel to each other. Furthermore, island-shaped floating gates 120 are formed at the respective intersections between the plurality of control gates 140 and the plurality of active areas ACT. Furthermore, a tunnel insulating layer (not illustrated) is interposed between each floating gate 120 and the substrate, and a gate dielectric layer is interposed between each floating gate 120 and the control gate 140 corresponding thereto. Each floating gate 120 forms a unit memory cell MC as a charge storage element.

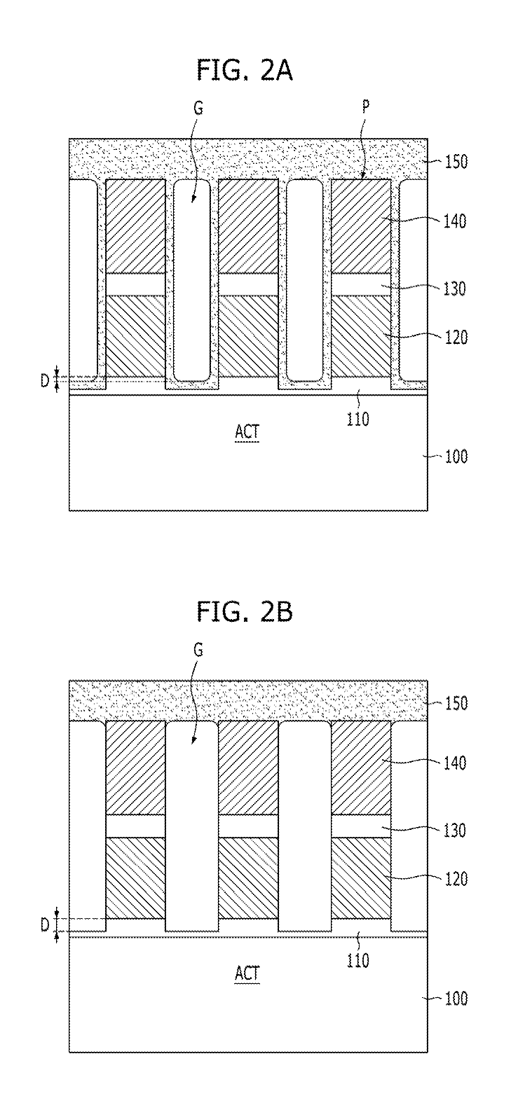

FIGS. 2A to 4B are cross-sectional views of nonvolatile memory devices in accordance with various embodiments of the present invention, taken along line I-I′ of FIG. 1.

Referring to FIG. 2A, a plurality of gate structures P is formed over a substrate 100. Each gate structure P includes a tunnel insulating layer 110, a floating gate 120, an inter-gate dielectric layer 130, and a control gate 140, which are sequentially stacked over the substrate 100.

The substrate 100 may include a semiconductor substrate formed of silicon. The tunnel insulating layer 110 for charge tunneling between the floating gate 120 and the substrate 100 may be formed of oxide, for example. The floating gate 120 serves to store charges. For example, the floating gate 120 may be formed of polysilicon doped with an impurity or the like, but the present invention is not limited thereto. The floating gate 120 may be formed of various conductive materials or insulating materials (for example, silicon nitride) that may store storing charges. The inter-gate dielectric layer 130 serves to block charge transfer between the floating gate 120 and the control gate 140. The inter-gate dielectric layer 130 may have a triple-layer structure of oxide-nitride-oxide (ONO), but the present invention is not limited thereto. The control gate 140 serves to control the floating gate 120. In this exemplary embodiment of the present invention, the control gate 140 may control another floating gates extended and arranged in the second direction. The control gate 140 may be formed of various conductive materials such as impurity-doped polysilicon, metal and the like. The control gate 140 may have a single-layer or triple-layer structure.

Over the substrate 100 having the gate structure P formed thereon, an interlayer dielectric layer 150 is formed as to cover the plurality of gate structures P. Here, the interlayer dielectric layer 150 may include a layer with a poor step coverage characteristic for example, an oxide layer deposited by a low pressure (LP) or plasma-enhanced (PE) method. Accordingly, an air gap G is formed between a gate structure and another gate structure adjacent thereto inside the interlayer dielectric layer 150. FIG. 2A illustrates that the air gap G is surrounded by the interlayer dielectric layer 150, but the present invention is not limited thereto. The air gap G may have various shapes depending on the type and formation method of the interlayer dielectric layer 150.

In this exemplary embodiment of the present invention, the tunnel insulating layer 110 may exist on the entire surface of the active area ACT of the substrate as well as under the floating gate 120. In this case, the surface of a first portion of the tunnel insulating layer 110 disposed under the air gap P is positioned at a lower level than the surface of a second portion of the tunnel insulating layer 110 disposed under the floating gate 120. Therefore, the bottom surface of the air gap G between the adjacent gate structures P may be positioned at a lower level than the surface of the second portion of the tunnel insulating layer 110 of the gate structure P (as referred to symbol D).

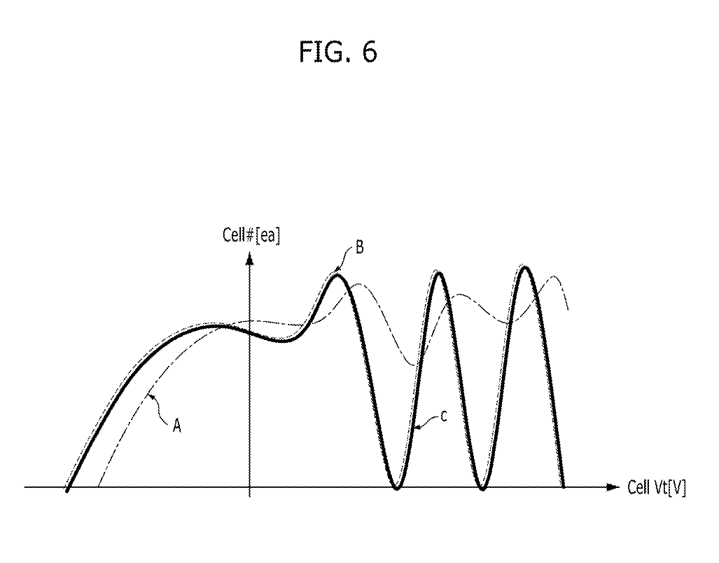

When the bottom surface of the air gap G is positioned at a lower level than the surface of the second portion of the tunnel insulating layer 110, the interference between the adjacent floating gates 120 significantly decreases compared with when the bottom surface of the air gap G is not positioned at a lower level than the surface of the second portion of the tunnel insulating layer 110. Accordingly, although the design rule shrinks, it is possible to acquire a desired cell distribution. This has been experimentally verified, and will be described below with reference to FIG. 6.

Referring to FIG. 2B, the gate structure P and the tunnel insulating layer 110 have substantially the same shape as those of FIG. 2A, but the air gap G has a different shape.

In this exemplary embodiment of the present invention, the interlayer dielectric layer 150 is positioned only over the air gap G, and does not exist on the side and bottom surfaces of the air gap G. Accordingly, the side surfaces of the air gap G may be directly contacted with the gate structure P, and the bottom surface of the air gap G may be directly contacted with the surface of the first portion of the tunnel insulating layer 110. The structure based on this embodiment of the present invention may be formed when the step coverage characteristic of the interlayer dielectric layer 150 is worse than in the embodiment of FIG. 2A.

In this embodiment of the present invention, the level difference (as referred to symbol D) between the bottom surface of the air gap G and the surface of the second portion of the tunnel insulating layer 110 of the gate structure P may be larger than that in the embodiment of FIG. 2A. Accordingly, the inter-cell interference prevention effect may be further improved.

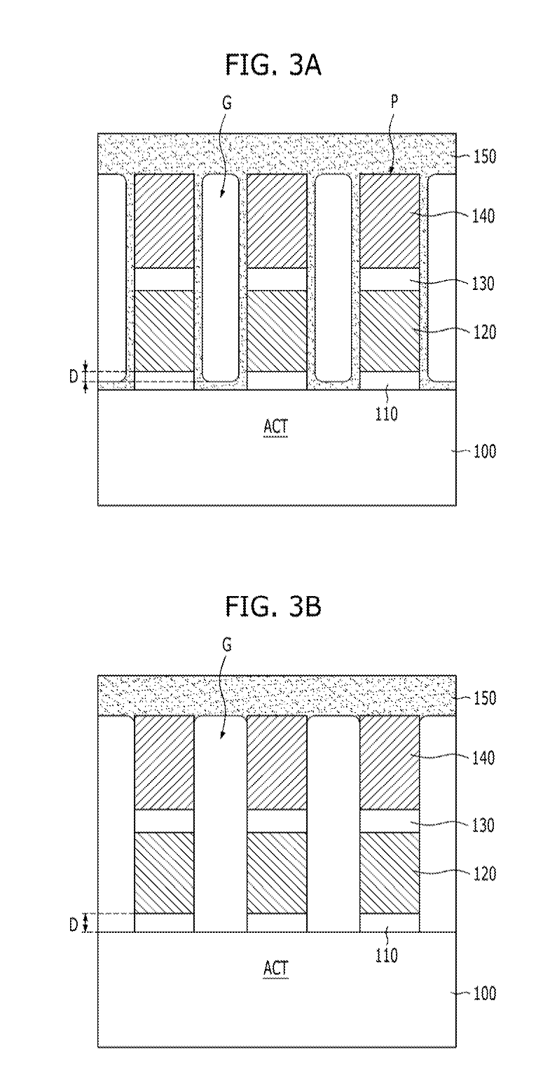

Referring to FIG. 3A, the tunnel insulating layer 110 has a different shape from the tunnel insulating layer 110 of FIG. 2A.

In this exemplary embodiment of the present invention, the tunnel insulating layer 110 has the same plane shape as the floating gate 120. Accordingly, the tunnel insulating layer 110 exists, for example, only under the floating gate 120, and does not exist in the other areas. In other words, the tunnel insulating layer 110 does not exist under the air gap G.

Therefore, the bottom surface of the aft gap G may be positioned at a lower level in this embodiment than in the embodiment of FIG. 2A. Accordingly, a level difference (as referred to symbol D) between the bottom surface of the air gap G and the surface of the tunnel insulating layer 110 may increase. Accordingly, the inter-cell interference prevention effect may be further improved.

Referring to FIG. 3B, the gate structure P has substantially the same shape as that of FIG. 3A, but the air gap G has a different shape.

In this exemplary embodiment of the present invention, the interlayer dielectric layer 150 is positioned, for example, only over the air gap G. Furthermore, the side surface of the air gap G may be directly contacted with the gate structure P, and the bottom surface of the air gap G may be directly contacted with the substrate 100. Therefore, a level difference (as referred to symbol D) between the bottom surface of the air gap G and the surface of the tunnel insulating layer 110 in this embodiment may be larger than that in the embodiment of FIG. 3A. Accordingly, the inter-cell interference prevention effect may be further improved.

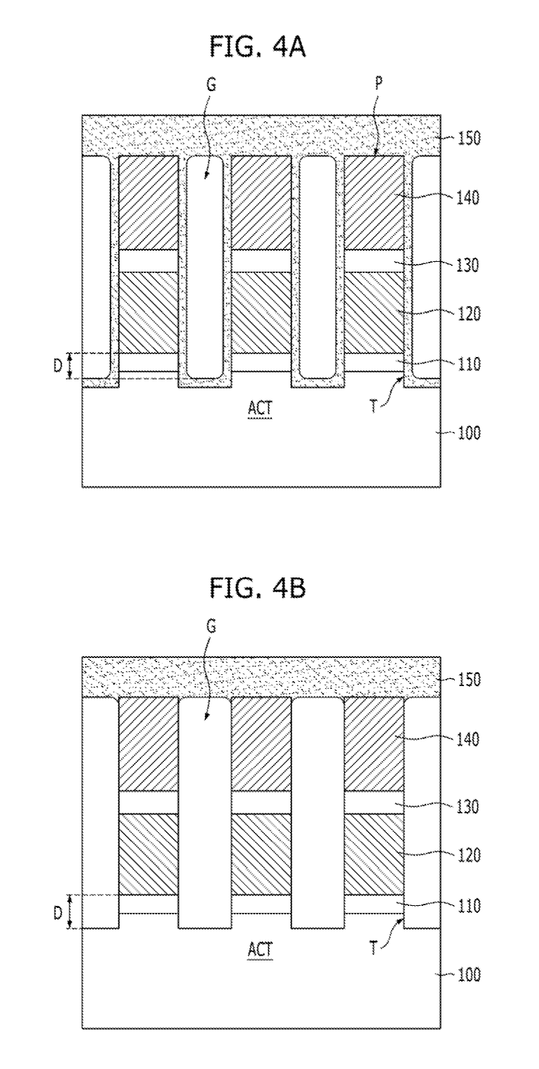

Referring to FIG. 4A, the substrate 100 has a different shape from that of FIG. 3A.

In this exemplary embodiment of the present invention, the tunnel insulating layer 110 has the same plane shape as the floating gate 120. Furthermore, a part of the substrate 100 exposed by the gate structure P is removed to form a trench T at a predetermined depth inside the substrate 100. The air gap G is disposed over the trench T.

Therefore, the bottom surface of the air gap G may be positioned at a lower level in this embodiment than in the embodiment of FIG. 3A. Accordingly, a level difference (as referred to symbol D) between the bottom surface of the air gap G and the surface of the tunnel insulating layer 110 in this embodiment may become larger than that in the embodiment of FIG. 3A. That is because the level of the bottom surface of the air gap G may be decreased by the depth of the trench T. As a result, the inter-cell interference prevention effect may be further improved.

Referring to FIG. 4B, the gate structure P and the substrate 100 have substantially the same shape as those of FIG. 4A, but the air gap G has a different shape.

In this exemplary embodiment of the present invention, the interlayer dielectric layer 150 may be positioned only over the air gap G, the side surfaces of the air gap G may be directly contacted with the gate structure P and the bottom surface of the air gap G may be directly contacted with the trench T. Therefore, a level difference (as referred to symbol D) between the bottom surface of the air gap G and the surface of the tunnel insulating layer 110 in this embodiment may be larger than that in the embodiment of FIG. 4A. Accordingly, the inter-cell interference prevention effect may be further improved.

The above-described embodiments of the present invention have a common feature that the bottom surface of the air gap G is positioned at a lower level than the surface of the tunnel insulating layer 110. As the surface level of the tunnel insulating layer 110 and/or the surface level of the substrate 100 under the air gap G decreases, the bottom surface of the air gap G may be positioned at a lower level. The shape of the air gap G may be modified in various manners. As illustrated in FIG. 2A, the air gap G may be surrounded by the interlayer dielectric layer 150. Alternatively, as illustrated in FIG. 2B, the interlayer 150 may exist, for example, only over the air gap G, and may not exist on the side and bottom surfaces of the air gap G. Furthermore, although not illustrated, the interlayer dielectric layer 150 may exist is on the top and side surfaces of the air gap G, and may not exist on the bottom surface of the air gap G. Alternatively, the interlayer dielectric layer 150 may exist on the top and bottom surfaces of the air gap G, and may not exist on the side surfaces of the air gap G.

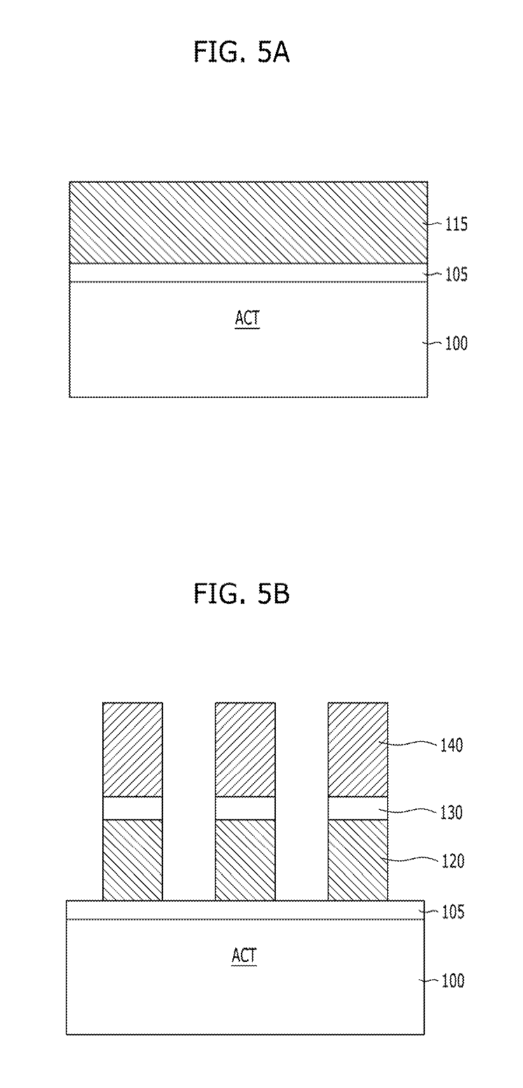

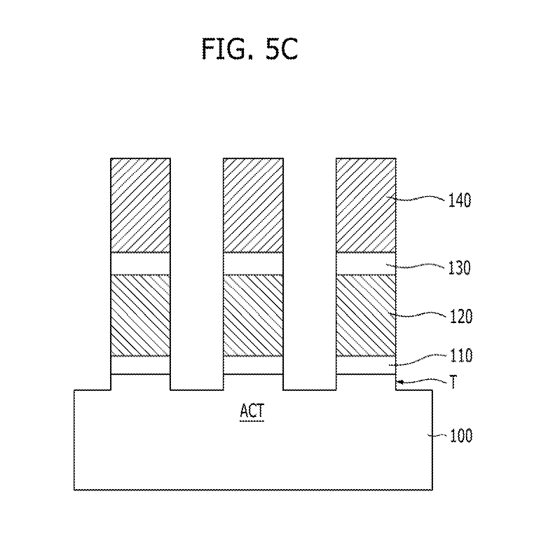

FIGS. 5A to 5C are cross-sectional views illustrating a method for fabricating the nonvolatile memory device in accordance with the exemplary embodiment of the present invention. FIGS. 5A to 5C illustrate intermediate steps for fabricating the devices of FIG. 4A to 4B.

Referring to FIG. 5A, a stacked structure of an insulating layer 105 and a conductive layer 115 is formed over a substrate 100. The insulating layer 105 is formed of a material to form the tunnel insulating layer 110 as described below, and the conductive layer 115 is formed of a material to form the floating gate 120 as described below. Here, the stacked structure of the insulating layer 105 and the conductive layer 115 may have the same plane shape as the active area ACT. As described above, an insulating layer such as silicon nitride having a charge trapping characteristic may be used instead of the conductive layer 115.

The process to form the stacked structure of the insulating layer 105 and the conductive layer 115 will be described in more details. First, an insulating material and a conductive material are sequentially deposited on the entire surface of the substrate 100, and a mask pattern is then formed to cover the active area. Then, the conductive material and the insulating material are etched using the mask pattern as an etch barrier. The substrate 100 exposed by etching the conductive material and the insulating material is then etched to a predetermined depth. Then, an isolation trench is formed in the substrate 100 so as to define the active area. Subsequently, an insulating layer is buried in the isolation trench to form an isolation layer (not illustrated).

Referring to FIG. 5B a material to form the inter-gate dielectric layer 130 and a conductive material to form the control gate 140 are sequentially deposited on the resulting structure of FIG. 5A. These materials are then selectively etched to form a plurality of control gates 140 and a plurality of inter-gate dielectric layers 130, extending in a direction crossing the active area ACT of the substrate 100.

The conductive layer 115 exposed by the formation of the plurality of control gates 140 and the plurality of inter-gate insulating layers 130 is etched to form a plurality of floating gates 120. The etching process for the conductive layer 115 may be performed using the insulating layer 105 as an etch stop layer. Each floating gate 120 is formed by etching the conductive layer 115 having the same plane shape as the active area ACT in the direction crossing the active area ACT. Therefore, the floating gate 120 has an island shape.

Referring to FIG. 5C, the insulating layer 105 exposed by the formation of the plurality of floating gate 120 is etched to form the tunnel insulating layer 110 having the same plane shape as the floating gate 120, and the substrate 100 exposed by the formation of the tunnel insulating layer 110 is etched to a predetermined depth to form a trench T inside the substrate 100.

Referring to FIG. 4A or 4B, an interlayer dielectric layer 150 is formed over the resulting structure of FIG. 5C. The interlayer dielectric layer 150 may be formed of an insulating material such as oxide. At this time, as the interlayer dielectric layer 150 is formed by the LP or PE method so that the step coverage characteristic is degraded, the air gap G may be formed in the interlayer dielectric layer 150. In particular, because the air gap G is positioned over the trench T between the adjacent gate structures P, the bottom surface of the air gap G may be positioned at a low level than the surface of the tunnel insulating layer 110 of the gate structure P.

Meanwhile, when the etching depth of the tunnel insulating layer 110 and/or the substrate 100 is controlled during the process of FIG. 5C, any one of the devices of FIGS. 2A to 3B may be fabricated. For example, when the insulating layer 105 exposed by the formation of the floating gate 120 is etched during the process of FIG. 5C, the etching may be stopped at a time point when a part of the insulating layer 105 is left, and the formation process of the interlayer dielectric layer 150 may be then performed to fabricate the device of FIG. 2A or 2B. Alternatively, the entire part of the insulating layer 105 exposed by the formation of the floating gate 120 may be etched during the process of FIG. 5C, the etching process may be stopped at a time point when the substrate 100 is exposed, and the formation process of the interlayer dielectric layer 150 may be then performed to fabricate the device of FIG. 3A to 3B.

FIG. 6 is a graph showing the effect of the present invention. In particular, FIG. 6 shows distributions of cells based on the threshold voltages of the cells.

Referring to FIG. 6, a line B indicates a cell distribution when the bottom surface of an air gap between adjacent gate structures in a nonvolatile memory device having a predetermined design rule is positioned at a higher level than the surface of a tunnel insulating layer of the gate structure. A line A indicates a cell distribution when the bottom surface of an air gap between gate structures in a nonvolatile memory device having a smaller design rule than the nonvolatile memory device of the line B is positioned at a higher level than the surface of a tunnel insulating layer of the gate structure. A line C indicates a cell distribution when the bottom surface of an air gap between adjacent gate structures in a nonvolatile memory device having the same design rule as the nonvolatile memory device of the line A is positioned at a lower level than the surface of a tunnel insulating layer of the gate structure.

Referring to the lines A and B, a normal cell distribution may be obtained at a specific design rule, even though the bottom surface of the air gap is positioned at a higher level than the surface of the tunnel insulating layer. However, when the design rule is further reduced, a normal cell distribution may not be obtained.

Referring to the lines A and C, a normal cell distribution may be obtained in a similar manner to the line B, when the bottom surface of the air gap is positioned at a lower level than the surface of the tunnel insulating layer, although the design rule is reduced.

As a result, when the air gap formation technology is used, the limit caused by the reduction in design rule may be overcome by lowering the level of the bottom surface of the air gap.

In accordance with the exemplary embodiments of the present invention, inter-cell interference despite the reduction in design rule may be prevented to acquire a desired cell distribution.

While the present invention has been described with respect to the specific embodiments, it will be apparent to those skilled in the art that various changes and modifications may be made without departing from the spirit and scope of the invention as defined in the following claims.

What is claimed is:

1. A nonvolatile memory device comprising:
a plurality of gate structures formed over a substrate, wherein each gate structure comprises a tunnel insulating layer, a floating gate, an inter-gate dielectric layer, and a control gate, which are sequentially stacked over the substrate; and
an interlayer dielectric layer covering the plurality of gate structures and having an air gap formed between a gate structure and another gate structure adjacent thereto,
wherein the bottom surface of the air gap is positioned at a lower level than the surface of the tunnel insulating layer.

2. The nonvolatile memory device of claim 1, wherein the tunnel insulating layer exists even under the air gap, and wherein
the surface of a first portion of the tunnel insulating layer under the air gap is positioned at a lower level than the surface of a second portion of the tunnel insulating layer under the floating gate.

3. The nonvolatile memory device of claim 1, wherein the tunnel insulating layer does not exist under the air gap.

4. The nonvolatile memory device of claim 1, wherein the surface of a first portion of the substrate under the air gap is positioned at a lower level than the surface of a second portion of the substrate under the gate structure.

5. The nonvolatile memory device of claim 1, wherein the gap is surrounded by the interlayer dielectric layer.

6. The nonvolatile memory device of claim 2, wherein the bottom surface of the air gap is directly contacted with the first portion of the tunnel insulating layer under the air gap.

7. The nonvolatile memory device of claim 3, wherein the bottom surface of the air gap is directly contacted with a first portion of the substrate under the air gap.

8. A method for fabricating a nonvolatile memory device, comprising:
forming a first insulating layer for a tunnel insulating layer, a material layer for a floating gate, a second insulating layer for an inter-gate insulating layer, and a conductive layer for a control gate, over a substrate;
selectively etching the conductive layer and the second insulating layer;
etching the material layer exposed by the etching of the conductive layer and the second insulating layer;
forming a plurality of gate structures, wherein each gate structure is formed by etching at least a part of the first insulating layer exposed by the etching of the material layer, and each gate structure includes a tunnel insulating layer, a floating gate, an inter-gate dielectric layer, and a control gate, which are stacked therein; and
forming an interlayer dielectric layer covering the plurality of gate structures and having an air gap formed between a gate structure and another gate structure adjacent thereto,
wherein the bottom surface of the air gap is positioned at a lower level than the surface of the tunnel insulating layer.

9. The method of claim 8, wherein, in the forming of the gate structure,
the entire part of the first insulating layer is etched to expose the substrate.

10. The method of claim 8, wherein, in the forming of the gate structure,
the entire part of the first insulating layer is etched, and a part of the substrate exposed by the etching of the entire part of the first insulating layer is further etched.

11. The method of claim 8, wherein the air gap is formed to be surrounded by the interlayer dielectric layer.

12. The method of claim 8, wherein the air gap is formed to be directly contacted with a portion of the first insulating layer under the air gap.

13. The method of claim 9, wherein the bottom surface of the air gap is formed to directly contact with a portion of the substrate under the air gap.

14. A method for fabricating a nonvolatile memory device, comprising:
forming a plurality of gate structures over a substrate, wherein each gate structure includes a tunnel insulating layer; and
forming an interlayer dielectric layer covering the plurality of gate structures and having an air gap formed between a gate structure and another gate structure adjacent thereto,
wherein the bottom surface of the air gap is positioned at a lower level than the surface of the tunnel insulating layer.

15. The method of claim 14, wherein the forming of a plurality of gate structures comprises:
forming a first insulating layer for the tunnel insulating layer, a material layer for a floating gate, a second insulating layer for an inter-gate insulating layer, and a conductive layer for a control gate, over the substrate;
selectively etching the conductive layer and the second insulating layer; and
etching the material layer exposed by the etching of the conductive layer and the second insulating layer,
wherein each gate structure is formed by etching at least a part of the first insulating layer exposed by the etching of the material layer, and each gate structure further includes a floating gate, an inter-gate dielectric layer, and a control gate, which are stacked therein.

16. The method hod of claim 15, wherein, in the forming of the gate structure,
the entire part of the first insulating layer is etched to expose the substrate.

17. The method of claim 15, wherein, in the farming of the gate structure,
the entire part of the first insulating layer is etched, and a part of the substrate exposed by the etching of the entire part of the first insulating layer is further etched.

18. The method of claim 15, wherein the air gap is formed to be surrounded by the interlayer dielectric layer.

19. The method of claim 15, wherein the air gap is formed to be directly contacted with a portion of the first insulating layer under the air gap.

20. The method of claim 16, wherein the bottom surface of the air gap is formed to directly contact with a portion of the substrate under the air gap.
